(19) United States
(12) Patent Application Publication
(10) Pub. No.: US 2014/0336963 A1
(43) Pub. Date: Nov. 13, 2014

(54) METHODS AND APPARATUS FOR COMMUNICATING AVAILABLE BATTERY POWER

(71) Applicants: Gang Ji, Santa Clara, CA (US); Alexander B. Uan-Zo-li, Hillsboro, OR (US); Mazen G. Gedeon, Hillsboro, OR (US); Jorge P. Rodriguez, Portland, OR (US); Basavaraj B. Astekar, Hillsboro, OR (US)

(72) Inventors: Gang Ji, Santa Clara, CA (US); Alexander B. Uan-Zo-li, Hillsboro, OR (US); Mazen G. Gedeon, Hillsboro, OR (US); Jorge P. Rodriguez, Portland, OR (US); Basavaraj B. Astekar, Hillsboro, OR (US)

(21) Appl. No.: 13/976,093

(22) PCT Filed: Mar. 30, 2012
(86) PCT No.: PCT/US2012/031624

§ 371 Date: Jul. 15, 2014

(51) Int. Cl. G01R 31/36; G06F 11/30

(52) U.S. Cl. CPC G01R 31/3648; G06F 11/3062; G01R 31/3606
USPC 702/63

(57) ABSTRACT

Systems and methods of enabling a battery system to intelligently provide its current support capability include logic to determine current battery power status information. The current battery power status information may be compared with a set of programmed battery power status information to determine a match. There may be logic to indicate the current battery power status information based on the match.

### BACKGROUND

Different power management techniques have been developed to enable users of mobile computing devices to operate using battery power for an extended period of time.

However, these techniques are generally applied without much knowledge about the status of the battery power.

### BRIEF DESCRIPTION OF THE DRAWINGS

The various advantages of the embodiments of the present invention will become apparent to one skilled in the art by reading the following specification and appended claims, and by referencing the following drawings, in which:

FIG. 1 is a block diagram that illustrates an example computer system, in accordance with some embodiments;

FIG. 2 is a block diagram that illustrates an example battery system, in accordance with some embodiments;

FIG. 3A is a block diagram that illustrates an example of a battery status determination logic;

FIG. 3B is a block diagram that illustrates an example of an interface register;

FIG. 4 is a block diagram that illustrates an example of the different power ranges of battery power status information;

FIG. 5 is a block diagram that illustrates an example of a battery system that generates battery power status information for a computing device with an embedded controller and a central processing unit (CPU);

FIG. 6 is a flowchart of an example method of providing the battery power status information using an active approach;

FIG. 7 is a flowchart of an example of providing battery power status information using a passive approach.

### DETAILED DESCRIPTION

Embodiments may involve an apparatus which may include logic to determine current battery power status information of a battery system. There may be logic to compare the current battery power status information with a set of programmed battery power status as well as voltage and resistance parameters information to determine a match, and there may be logic to indicate the current battery power status information based on the match.

Embodiments may involve a system which may include a processor and a

a battery system coupled with the processor. The battery system may be configured to determine current battery power status information. The battery system may be configured to provide the current battery power status information based on a. match with a member of a set of programmed battery power status information.

Embodiments may involve a computer implemented method which may include determining current battery power status information of a battery system. The method may also include comparing the current battery power status information with programmed battery power status information to deter nine a match. The programmed battery power status information may be stored in a memory of the battery system.

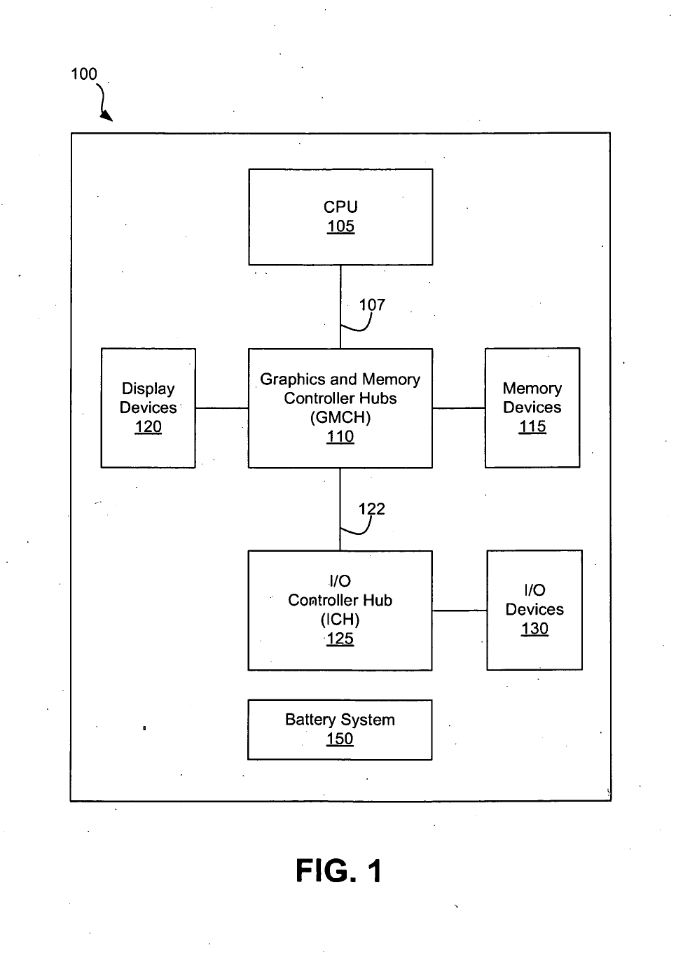

Turning to FIG. 1, a block diagram that illustrates an example computer system 100 is shown, in accordance with some embodiments. The computer system 100 may include a central processing unit (CPU) 105, a graphics and memory controller hub

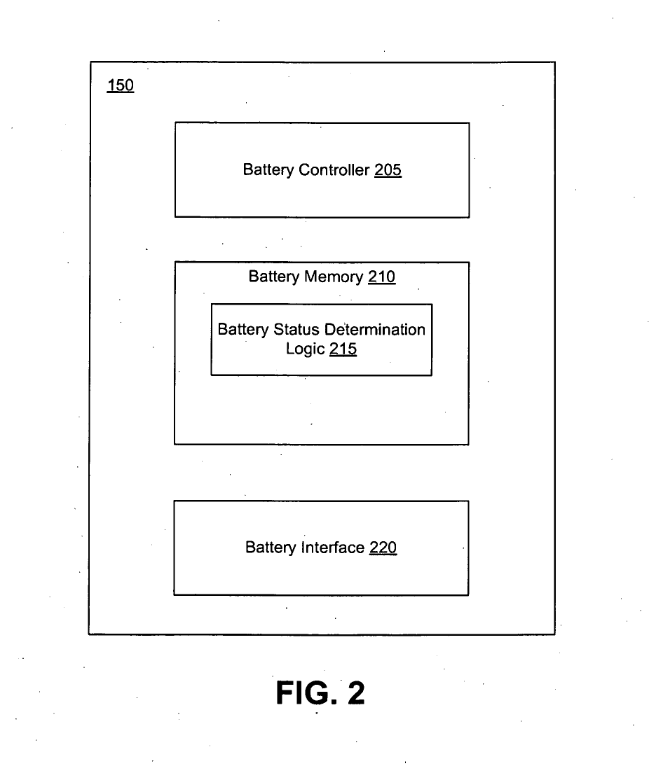

(GMCH) 110, and an input/output controller hub (ICH) 125, The GMCH 110 may be coupled to the CPU 105 via a bus 107. The ICH 125 may be coupled to the GMCH 1110 via a bus 122. The GMCH 110 may also be coupled to memory devices 115 and display devices 120. The ICH 125 may be coupled to I/O devices 130. The GMCH 110 may include a graphics system 200 (shown in FIG. 2). Although the CPU 105, the GMCH 110 and the ICH 125 may be illustrated as separate components, the functions of two or more of these components may be combined. A power supply 150 may be used to provide power to the computer system 100. The power supply 150 may be a battery (referred to herein as a battery system 150) or an external power source. The computer system 100 may also include many other components; however, for simplicity, they are not shown.

Turning to FIG. 2, a block diagram that illustrates an example battery system 150 is shown, in accordance with some embodiments. The battery system 150 may be a smart battery system and may include a battery controller 205, battery memory 210 and battery interface 220. The battery controller 205 may be configured to perform operations that enable the battery system 150 to protect the battery life. For example, this may include operations that prevent overcharging and operations that control discharging. The battery memory 210 may be configured to store instructions and information that may be used by the battery controller 205. The instructions and information may be provided by the battery manufacturer. it may be possible for the instructions and information to be subsequently modifiable. For example, the instructions and information may be stored in a firmware (such as, for example, a read-only memory or a flash memory) and can be replaced.

For some embodiments, the battery memory 210 may include battery status determination logic 215, which may be configured to determine a current battery power status information of the battery system 150. For example, the battery status determination logic 215 may be configured to determine a range of battery power levels that the battery system 150 may be able to support. The battery status determination logic 215 may be configured to determine a minimum voltage that the battery system 150 can provide. The battery interface 220 may be configured to enable the battery system to provide information about an amount of power that the battery system 150 can support. The battery system 150 may be designed according to the Smart Battery System Specification (e.g., Revision 1.0, Benchmarq Microelectronics Inc. et al, 1996). Although not shown, the battery system 150 may be associated with a battery charger.

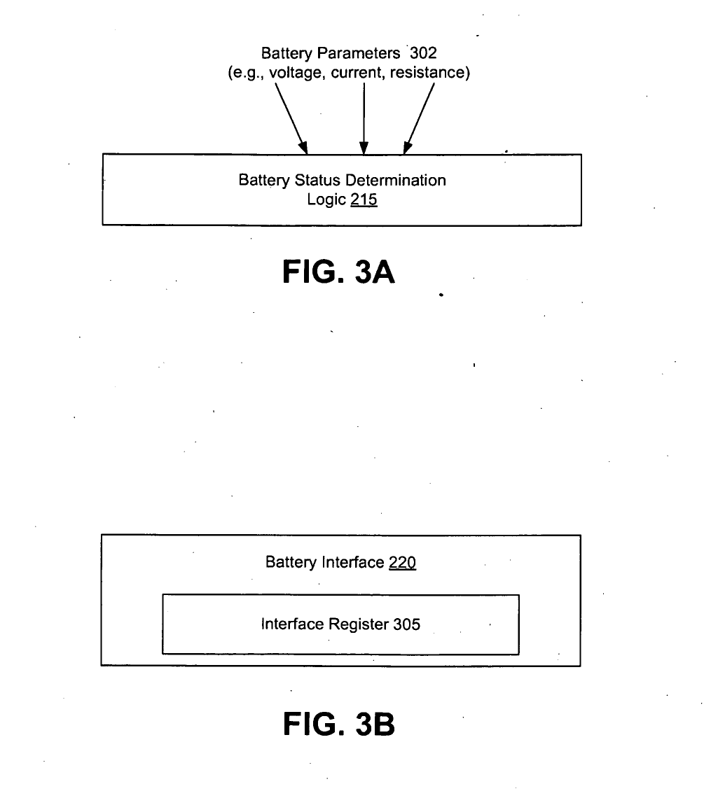

Turning to FIG. 3A, the battery status determination logic 215 is shown. For some embodiments, the battery status determination logic 215 may be configured to receive battery parameters 302 in order to determine current battery power status information that the battery system 150 can support. For example, the battery parameters 302 may include one or more voltage parameters, one or more current parameters, and one or more resistance parameters, For some embodiments, the battery parameters may be programmable. The battery status determination logic 215 may be implemented in software, hardware or a combination of both.

For some embodiments, the battery interface 220 may include an interface register 305 which may be used by the battery system 150 to indicate the battery power status information. An example of the interface register 305 is shown in FIG. 3B. The interface register 305 may be a one bit register or a multiple bit register. For example, when using only one bit, the bit may be set to a value of “1” when the battery power status information (e.g., power level) of the battery system 150 (FIG. 2) is above a certain predetermined level, and set to a value of “0” when the power level of the battery system 150 (FIG. 2) is below that predetermined level.

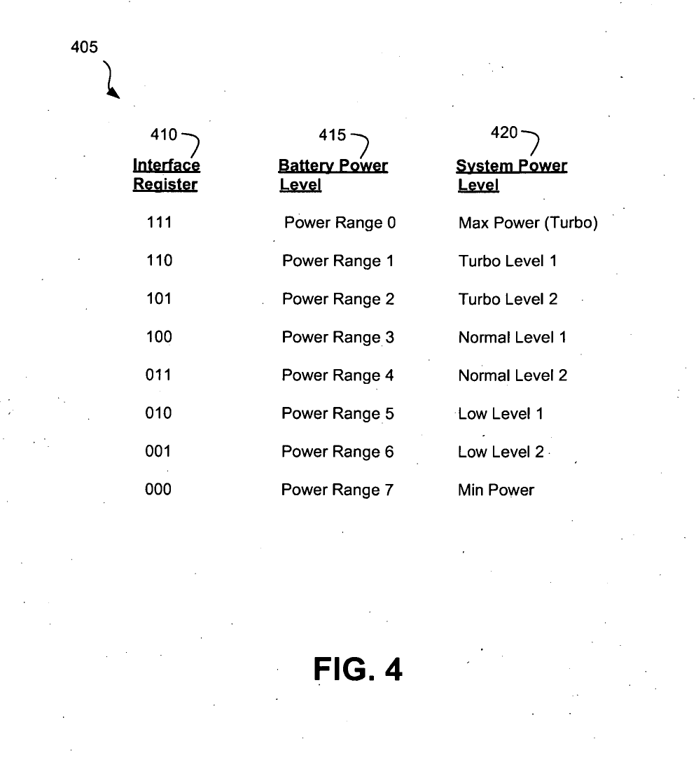

When multiple bits are used for the interface register 305, different battery power status information or different ranges of battery power status information may be available. For example, when three bits are used, eight different members or ranges of battery power status information may be used. An example of the different ranges is shown in table 405 of FIG. 4. Column 410 may illustrate the different possible hit values for the three-bit interface register 305. Column 415 may illustrate the different power levels or ranges of power levels that the battery system 150 may be able to support. For example, the bit values of “101” may correspond to a power level range 2. Column 420 may illustrate the power modes that the computer system 100 may operate based on the power level that the battery system 150 can support. For example, when the bit values of the interface register 305 are “111”, the computer system 100 may operate at maximum power or turbo mode.

For some embodiments, the different bit values and the corresponding battery power status information may be specified by the manufacturer of the battery system 150 and may be stored in the battery memory 210. For example, with continuing reference to

FIGS. 2-4, when the battery status determination logic 215 determines that the current power level that battery system 150 can support is within the power range 2 (as shown in table 405), that information may be transmitted to the battery interface 220 to cause the interface register 305 to be set to the value “101”.

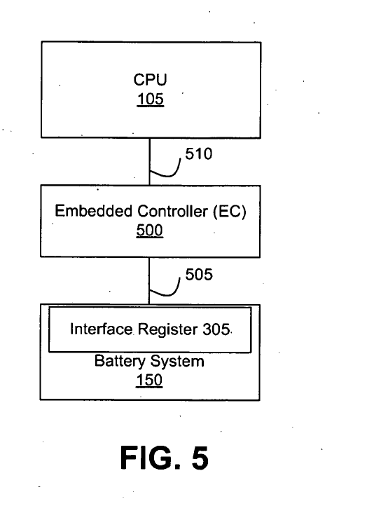

FIG. 5 is a block diagram that shows an example embodiment of the battery system generating battery power status information. For some embodiments, the battery system 150 may operate in an active mode where it periodically causes the battery status determination logic 215 (shown in FIG. 3A) to determine the current battery power status information. The frequency of the operations of the battery status determination logic 215 may be determined by the manufacturer, or it may be programmable. The result of the operations may then be reflected in the interface register 305. An embedded controller 500 in the computer system 100 may access the battery power status information from the interface register 305 via bus 505. The battery power status information may then be sent to the CPU 105 via bus 510, The CPU 105 may then adjust its operation mode based on the battery power status information.

For some embodiments, the battery system 150 may operate in a passive mode where it may cause the battery status determination logic 215 to determine the battery power status information upon request. For example, the CPU 105 may determine that, in order to perform operations in certain operation mode (e.g., turbo mode), the CPU 105 may need the battery system 150 to be able to support that operation mode (e.g., satisfy power requirement for the turbo mode). The CPU 105 may send the requirement to the embedded controller 500 via the bus 510. The embedded controller 500 may in turn send the requirement to the battery system 150. The battery system 150 may then cause the battery status determination logic 215 to determine the current battery power status information. The battery system 150 may then compare the current battery power status information with the requirement to determine if the requirement may be satisfied. The battery system 150 may then set the interface register 305 accordingly. This passive mode may be referred to as a negotiation mode where the embedded controller 500 negotiates with the battery system 150 until the battery system 150 indicates that it can support the requirement.

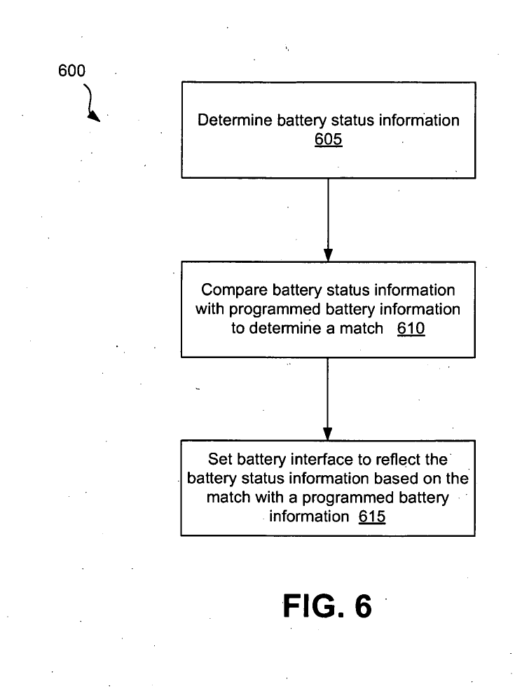

Turning to FIG. 6, an example flow diagram illustrating a process performed by the battery system. The process may correspond to the battery system 150 operating in the active mode described above. At block 605, the battery system 150 may cause the battery information determination logic 215 to determine the current battery power status information. At block 610, the current battery power status information may be compared with programmed battery information, An example of the predetermined battery information is shown in FIG. 4. At block 615, the battery system 1150 may set the battery interface to reflect the battery power status information based on a match with the programmed battery information. This may include setting the interface register to a value that corresponds to the programmed battery information,

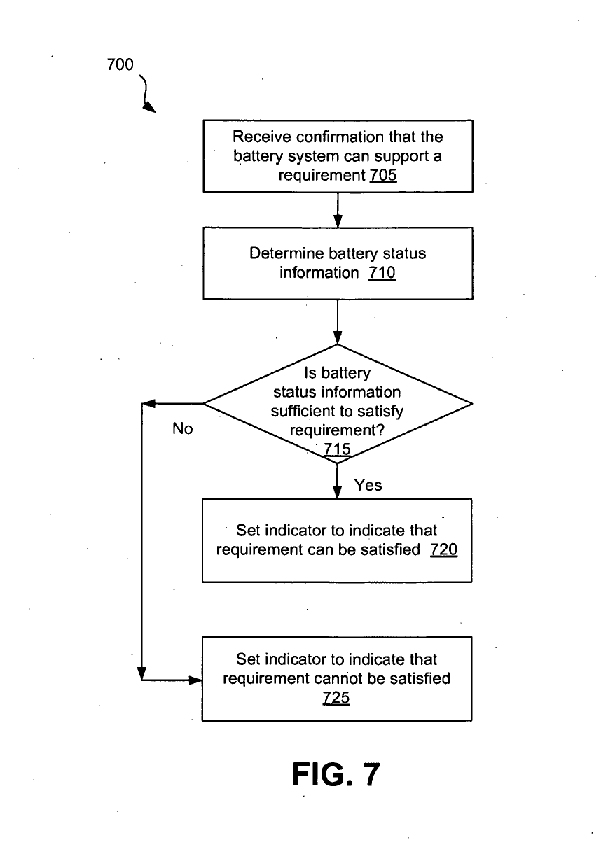

Turning to FIG. 7, an example flow diagram illustrating another process performed by the battery system. The process may correspond to the battery system 150 operating in the passive mode described above, At block 705, the battery system 150 may receive a request to confirm whether the battery system 150 is able to support a requirement. For example, the CPU 105 (shown in FIG. 1) may need to enter a turbo mode for a certain period of time and want to confirm that the battery system 150 is able to deliver enough power to sustain the turbo mode (e.g., “111” as shown in FIG. 4). At block 710, the battery system 150 may cause the battery power status information logic 215 to determine the current battery power status information. At block 715, the current battery power status information may be compared with the programmed battery power status information to determine a match (e.g., “011” as shown in FIG. 4). The match value (e.g., “011”) may then be compared with the requirement (e.g., “111”) to determine whether the battery system 150 can satisfy the requirement. If the requirement cannot be satisfied, the process may flow from block 715 to block 725 where a negative indicator may be set. If the requirement can be satisfied, the process may flow from block 715 to block 720 where a positive indicator may be set.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

Example sizes/models/values/ranges may have been given, although embodiments of the present invention are not limited to the same. As manufacturing techniques (e.g., photolithography) mature over time, it is expected that devices of smaller size could be manufactured. In addition, well known power/ground connections to integrated circuit (IC) chips and other components may or may not be shown within the figures, for simplicity of illustration and discussion, and so as not to obscure certain aspects of the embodiments of the invention. Further, arrangements may be shown in block diagram form in order to avoid obscuring embodiments of the invention, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments of the invention, it should be apparent to one skilled in the art that embodiments of the invention can be practiced without, or with variation of these specific details. The description is this to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections, in addition, the terms “first”, “second”, etc. might be used herein only to facilitate discussion, and carry no particular temporal or chronological significance unless otherwise indicated.

Those skilled in the art will appreciate from the foregoing description that the broad techniques of the embodiments of the present invention can be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

1-27. (canceled)

28. A computer-implemented method comprising:
receiving a support requirement related to a battery system;
determining current battery power status information of the battery system;
comparing the current battery power status information with programmed battery power status information to determine a match, wherein the programmed battery power status information is stored in a memory of the battery system;
indicating the current battery power status information based on the match between the current battery power status information and the programmed battery power status information; and
indicating whether the support requirement can be satisfied based on the indicated current battery power status information.

29. The method of claim 28, wherein indicating the current battery power status information comprises setting one or more bits of a register of an interface of the battery system.

30. The method of claim 28, wherein the current battery power status information is determined based on at least one of a voltage parameter, a current parameter and a resistance parameter.

31. The method of claim 28, wherein the programmed battery power status information is set by a manufacturer of the battery system and is modifiable.

32. The method of claim 28, wherein the current battery power status information is determined periodically or based on a request.

33. An apparatus comprising:
logic to determine current battery power status information of a battery system;
logic to compare the current battery power status information with a set of programmed battery power status information to determine a match; and
logic to indicate the current battery power status information based on the match.

34. The apparatus of claim 33, wherein the set of programmed battery power status information is to be stored in a memory of the battery system.

35. The apparatus of claim 33, wherein the logic to indicate the current battery power status information based on the match includes a logic to set one or more bits of a register of the battery system to reflect the match.

36. The apparatus of claim 35, wherein the logic to determine the current battery power status information is configured to perform periodically or based on a request.

37. The apparatus of claim 33, wherein the current battery power status information is to be determined based on at least one of a voltage parameter, a current parameter, and a resistance parameter.

38. The apparatus of claim 37, wherein the at least one of the voltage parameters, the current parameters, and the resistance parameters are programmable.

39. The apparatus of claim 33, wherein the set of programmed battery power status information includes one or more ranges.

40. A system comprising:
a processor; and
a battery system coupled with the processor, wherein the battery system is configured to determine current battery power status information and to provide the current battery power status information based on a match with a member of a set of programmed battery power status information.

41. The system of claim 40, wherein the current battery power status information is to be determined periodically.

42. The system of claim 40, wherein the current battery power status information is to be determined based on a request.

43. The system of claim 40, wherein the battery system includes a memory and the set of programmed battery power status information is stored in the memory of the battery system.

44. The system of claim 40, wherein the battery system includes a register configured to enable the processor to access the current battery power status information based on the set of programmed battery power status information.

45. The system of claim 40, wherein the set of programmed battery power status information is to be determined by a manufacturer of the battery system.

46. The system of claim 45, wherein the set of programmed battery power status information is to be modifiable.

47. A computer-implemented method comprising:
determining current battery power status information of a battery system; and
comparing the current battery power status information with programmed battery power status information to determine a match, wherein the programmed battery power status information is stored in a memory of the battery system.

48. The method of claim 47, further comprising receiving a support requirement related to the battery system.

49. The method of claim 48, further comprising indicating the current battery power status information based on the match between the current battery power status information and the programmed battery power status information.

50. The method of claim 49, wherein indicating the current battery power status information comprises setting one or more bits of a register of an interface of the battery system.

51. The method of claim 49, further comprising indicating whether the support requirement can be satisfied based on the indicated current battery power status information.

52. The method of claim 47, wherein the current battery power status information is determined based on at least one of a voltage parameter, a current parameter and a resistance parameter.

53. The method of claim 47, wherein the programmed battery power status information is set by a manufacturer of the battery system and is modifiable.

54. The method of claim 53, wherein the current battery power status information is determined periodically or based on a request.
